(19) United States
(12) Patent Application Publication
(10) Pub. No.: US 2024/0395634 A1
(43) Pub. Date: Nov. 28, 2024

(54) MOUNTING DEVICE AND MOUNTING METHOD

(71) Applicant: SAMSUNG ELECTRONICS CO., LTD., Suwon-si (KR)

(72) Inventor: Takamasa Sugiura, Yokohama (JP)

(21) Appl. No.: 18/647,760

(22) Filed: Apr. 26, 2024

(30) Foreign Application Priority Data
May 26, 2023 (JP) 2023-086949
Oct. 17, 2023 (KR) 10-2023-0138929

(51) Int. Cl. H01L 21/66; G06T 7/00; H01L 21/67; H01L 21/68; H01L 23/544

(52) U.S. Cl. CPC H01L 22/12; G06T 7/0006; H01L 21/67259; H01L 21/681; H01L 23/544; G06T 2207/30148; H01L 2223/54426

(57) ABSTRACT

A mounting device includes a profile acquisition unit, which, based on a captured image of a region including an alignment mark formed on a target object, obtains a luminance profile including a high-luminance region corresponding to the alignment mark and a plurality of low-luminance regions arranged on both sides of the high-luminance region, a fitting unit, which fits a fitting function including a sigmoid function having an inflection point and a curvature to the luminance profile and detects an edge position of the alignment mark from the inflection point, a position calculation unit, which calculates a center position of the alignment mark based on the detected edge position, and a bonding unit, which bonds an object to be bonded to another object to be bonded using the center position of the alignment mark.

### CROSS-REFERENCE TO RELATED APPLICATION

This application claims priority to Japanese Patent Application No. 2023-0086949, filed in the Japanese Intellectual Property Office on May 26, 2023, and Korean Patent Application No. 10-2023-0138929, filed in the Korean Intellectual Property Office on Oct. 17, 2023, respectively, the disclosures of which are incorporated by reference herein in their entirety.

### BACKGROUND

Semiconductor devices are becoming multilayered to achieve low power consumption and high driving speed. Semiconductor chip stacking processes, such as a chip on chip (CoC) process and a chip on wafer (CoW), or chip bonding processes of mounting semiconductor packages are changing from a connection method between contacts using wire bonding according to the related art to a connection method using flip chips or through-silicon vias (TSVs). In the connection method between contacts using the wire bonding, a bonding precision of several tens of micrometers (μm) is sufficient. However, flip chips, in which bumps and pads are in direct contact with each other, may require precision of several micrometers (μm). In particular, the chip bonding processes using TSVs may require precision of submicrometer (μm).

There is a method of recognizing alignment marks by using an upper and lower dual field-of-view (FOV) optical system during a bonding process (for example, JP 5876000 B2). Specifically, the upper and lower dual FOV optical system is inserted between a lower object to be bonded, which is held and supported by a bonding stage, and an upper object to be bonded, which is held and supported by a bonding head. Also, the upper and lower dual FOV optical system recognizes the alignment mark on a bonding surface of the lower object to be bonded and the alignment mark on a bonding surface of the upper object to be bonded. The upper and lower dual FOV optical system is formed by integrating a camera for recognizing an upper region with a camera for recognizing a lower region. The upper and lower dual FOV optical system has a driving shaft at least in a horizontal plane so that the upper and lower dual FOV optical system may be laterally inserted into a gap between the lower object and the upper object before bonding. Then, position alignment of the upper and lower objects is performed based on the results of recognition, and then, the upper and lower objects are bonded to each other.

In order to detect the position of the alignment mark, the position of an edge of the alignment mark is detected. As a method of detecting the position of an edge, for example, JP 5563942 B2 discloses an edge position detection device that obtains a luminance profile of a region including the edge of a pattern and detects the position of the edge of the pattern by applying a high-order approximation equation to a slope portion representing the edge of the pattern.

Also, JP 6355487 B2 discloses an edge position detection device that obtains a luminance profile of an inspection image that represents a group of pattern elements on a substrate. Then, the edge position detection device detects the position of the edge by applying a left-right symmetrical model function to a luminance profile having four concave portions and three convex portions which are alternately arranged. Here, the model function is obtained by combining four bell-shaped functions corresponding to the four concave portions with three bell-shaped functions corresponding to the three convex portions.

### SUMMARY

In general, in some aspects, the present disclosure is directed toward a mounting device and a mounting method that achieve high-precision mounting.

In general, according to some aspects, a mounting method includes detecting an alignment mark position of a first object and bonding the first object to a second object based on a position of the alignment mark, wherein the alignment mark position detecting method including capturing an image of a region including an alignment mark, obtaining a luminance profile of the image, and detecting a position of the alignment mark by fitting a fitting function into the luminance profile of the image, wherein the fitting function includes a sigmoid function having an inflection point and a curvature.

According to some aspects of the present disclosure, a mounting method includes capturing an image of a region including an alignment mark formed on an object to be bonded and acquiring a luminance profile, in a first direction, of a region of interest (ROI) including a first region, a second region and a third region arranged on the image in the first direction, fitting a fitting function, which includes a sigmoid function having an inflection point and a curvature, into the luminance profile of the ROI to thereby detect an edge position of the alignment mark from the inflection point, and bonding another object to be bonded to the object to be bonded using the detected edge position of the alignment mark, wherein the second region corresponds to the alignment mark, and the first region and the third region have a difference in luminance level from the second region, wherein the fitting function is expressed by

$$f ( x ) = ( \frac{1}{1 + exp ( - \frac{x - {μ}_{1}}{{a}_{1}} )} + \frac{1}{1 + exp ( - \frac{x - {μ}_{2}}{{a}_{2}} )} ) b + c ,$$

where μ₁ and μ₂ represent the inflection points, a₁ and a₂ represent the curvatures, and b and c represent constants.

According to some aspects of the present disclosure, a mounting method includes holding and supporting a first object to be bonded by a bonding head, holding and supporting a second object to be bonded by a bonding stage, wherein the second object to be bonded is bonded to the first object to be bonded, inserting an upper and lower dual field-of-view (FOV) optical system between the first and second objects to be bonded, capturing images of a first alignment mark and a second alignment mark by using a single image sensor in the upper and lower dual FOV optical system, wherein the first alignment mark corresponds to an alignment mark of the first object to be bonded and the second alignment mark corresponds to an alignment mark of the second object to be bonded, detecting a position of each of the first and second alignment marks, and bonding the first and second alignment marks to each other, wherein the detecting of the position of each of the first and second alignment marks includes capturing an image of regions including the first and second alignment marks, obtaining a luminance profile of the image, and detecting positions of the first and second alignment marks by fitting a fitting function into the luminance profile, wherein the fitting function includes a sigmoid function having an inflection point and a curvature.

### BRIEF DESCRIPTION OF THE DRAWINGS

Example implementations will be more clearly understood from the following detailed description, taken in conjunction with the accompanying drawings.

FIG. 1 is a diagram illustrating an example of a region of interest (ROI) of an image that includes an alignment mark in a method of detecting an edge position of the alignment mark according to some implementations.

FIG. 2 is a diagram illustrating the ROI of the image including the alignment mark, a region having high intensity of a luminance gradient, and the intensity of the luminance gradient in the method of detecting the edge position of the alignment mark according to some implementations.

FIG. 3 is a graph illustrating the intensity of the luminance gradient of the ROI in the method of detecting the edge position of the alignment mark according to some implementations.

FIG. 4 is a graph illustrating the intensity of the luminance gradient of the ROI in the method of detecting the edge position of the alignment mark according to some implementations.

FIG. 5 is a graph illustrating the intensity of the luminance gradient of the ROI in the method of detecting the edge position of the alignment mark according to some implementations.

FIG. 6 is a graph illustrating the intensity of the luminance gradient of the ROI in the method of detecting the edge position of the alignment mark according to some implementations.

FIG. 7 is a diagram illustrating an example of an ROI of an image that includes an alignment mark in a method of detecting an edge position of the alignment mark according to some implementations.

FIG. 8 is a graph illustrating an example of a luminance profile in the method of detecting the edge position of the alignment mark according to some implementations.

FIG. 9 is a diagram illustrating an example of misalignment of the ROI of the alignment mark according to some implementations.

FIG. 10 is a diagram illustrating an example of an alignment mark and the intensity of a luminance gradient in a method of detecting an edge position of the alignment mark according to some implementations.

FIG. 11 is a graph illustrating the intensity of the luminance gradient of the ROI in the method of detecting the edge position of the alignment mark according to some implementations.

FIG. 12 is a graph illustrating an example of a luminance profile of an ROI in a method of detecting an edge position of an alignment mark according to some implementations.

FIG. 13 is a configuration diagram illustrating an example of a mounting device according to some implementations.

FIG. 14 is a configuration diagram illustrating an example of an optical unit of an upper and lower dual field-of-view (FOV) optical system in the mounting device according to some implementations.

FIG. 15 is a diagram illustrating an example of an image of an alignment mark captured by an image sensor in the mounting device according to some implementations.

FIG. 16 is a block diagram illustrating an example of a processing device in the mounting device according to some implementations.

FIG. 17 is a diagram illustrating an example of a captured image of a region including an alignment mark formed on an object to be bonded in the mounting device according to some implementations.

FIG. 18 is a graph illustrating an example of a luminance profile and a fitting function in the mounting device according to some implementations.

FIG. 19 is a graph illustrating the fitting function in the mounting device according to some implementations.

FIG. 20 is a diagram illustrating examples of curvatures depending on coefficients of the fitting function in the mounting device according to some implementations.

FIG. 21 is a diagram illustrating examples of edge positions detected by the mounting device according to some implementations.

FIG. 22 is a diagram illustrating an example of a center position calculated by a position calculation unit in the mounting device according to some implementations.

FIG. 23 is a flowchart illustrating an example of a mounting method using the mounting device according to some implementations.

FIG. 24 is a flowchart illustrating an example of a method of detecting the center position of the alignment mark, according to some implementations.

FIG. 25 is a diagram illustrating an examples of an ROI that is cut out by a profile acquisition unit in the mounting method according to some implementations.

FIG. 26 is a diagram illustrating examples of data that is obtained by averaging the luminance of ROI in the mounting method according to some implementations.

FIG. 27 is a graph illustrating examples of repeatability when the size of the ROI is changed in the mounting method according to some implementations.

FIG. 28 is a graph illustrating an example of a case in which precision is deteriorated due to an increase in the size of the ROI in the mounting method according to some implementations.

FIG. 29 is a graph illustrating an example of a relationship between the size of the ROI and a calculation time in the mounting method according some implementations.

FIG. 30 is a diagram illustrating an example of a graphical user interface in the mounting device according to some implementations.

### DETAILED DESCRIPTION

Hereinafter, example implementations will be explained in detail with reference to the accompanying drawings. The same reference numerals are given to the same elements in the drawings, and repeated descriptions thereof are omitted.

The luminance of an image includes camera noise, such as a dark shot noise, a read noise, and a photon shot noise. When a group of images is captured for the same subject at different timings, the non-uniform luminance caused by camera noise can cause the results of a fitting function to vary between images. For instance, different edge positions may be detected in the image group for the same subject. This may lead to a deterioration in repeatability, which is undesirable in situations where high-precision position detection and mounting is required.

The present disclosure relates to improving the repeatability of detecting an edge position of an alignment mark by using a fitting function that allows high precision alignment, e.g., for alignment between objects to be bonded.

For example, According to some implementations, the mounting device detects an edge position of an alignment mark by a fitting process using a fitting function in order to perform alignment between target objects during a bonding process with high precision. Specifically, the mounting device obtains a luminance profile of a region of interest (hereinafter, referred to as an ROI) from an image including an alignment mark and a surrounding region of the alignment mark. Also, the mounting device fits a certain fitting function to the luminance profile. Accordingly, the mounting device detects the edge position of the alignment mark. Also, the mounting device bonds the target objects to each other on the basis of the detected edge positions.

There are several methods of obtaining the edge positions by fitting the fitting function to the luminance profile within the ROI. Also, the captured image has a variety of noise, and thus, luminance in the luminance profile is non-uniform. Due to this non-uniformity, different edge positions are detected between images captured at different times, even for the same subject. As a result, the repeatability in the edge position detection method deteriorates. In the embodiment, in order to suppress such non-uniformity, the size of the ROI of a fitting target is increased according to the principle of the law of large numbers.

In order to more clearly describe an edge position detection method used by the mounting device according to the embodiment, an edge position detection method according to a reference example is described below first. Then, a mounting device and an edge position detection method according to the embodiment is described while comparing with the reference example. In addition, the edge position detection method according to the reference example is also included in the technical idea of the embodiment. Also, the mounting device according to the embodiment does not exclude mounting the target objects using the edge position detection method according to the reference example.

An example of a method of detecting an edge position of an alignment mark according to some implementations is described below.

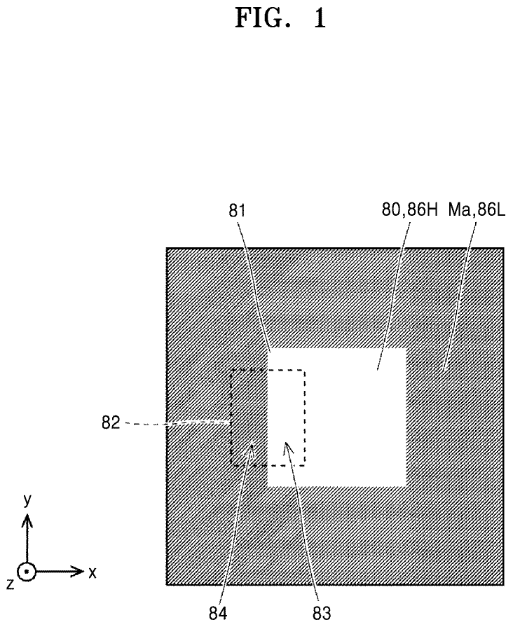

FIG. 1 is a diagram illustrating an example of a region of interest (ROI) of an image that includes an alignment mark in a method of detecting an edge position of the alignment mark according to some implementations. In FIG. 1, an ROI 82 of an image that includes an alignment mark 80 in a method of detecting an edge position 81 of the alignment mark 80. The method of detecting the edge position 81 of the alignment mark 80 uses the captured image of the alignment mark 80. The alignment mark 80 is formed on a certain surface of a target object Ma. The certain surface of the target object Ma includes a surface on which the alignment mark 80 is formed, for example, a bonding surface of the target object Ma, or includes an interface having a multi-layer structure.

A region, corresponding to the alignment mark 80, on the image is shown as a high-luminance region 86H. Additionally, a region other than the alignment mark 80 of the target object Ma on the image is shown as a low-luminance region 86L. The low-luminance region 86L has lower luminance than the high-luminance region 86H. The high-luminance region 86H has higher luminance than the low-luminance region 86L. In addition, the difference in luminance between the alignment mark 80 and a surrounding region of the alignment mark 80 is caused by the difference in reflectance. Accordingly, depending on wavelengths of illumination light illuminating the alignment mark 80, a region corresponding to the alignment mark 80 may become a low-luminance region and a surrounding region thereof may become a high-luminance region. Also, even when a transmission image is observed by irradiation with light transmitted from a bonding head or a bonding stage, a region corresponding to the alignment mark 80 becomes a low-luminance region and a surrounding region thereof becomes a high-luminance region. Accordingly, regions having a difference in luminance levels arranged in one direction on the image are referred to as a first region, a second region, and a third region. A region corresponding to the alignment mark 80 includes the second region. Regions, which are not included in the alignment mark 80 but located around the alignment mark 80, include the first region and the third region. The first region and the third region are located on both sides of the second region in one direction. Accordingly, the first region, the second region, and the third region are distinguished from each other. Hereinafter, the second region is described as a high-luminance region and the first region and the third region are described as low-luminance regions. Also, as described above, it is not excluded that the second region corresponds to a low-luminance region and the first region and the third regions correspond to high-luminance regions.

The ROI 82 partially includes the alignment mark 80 formed on the target object Ma. Specifically, the ROI 82 includes one side portion 83 of the alignment mark 80 and a peripheral region 84 adjacent to the side portion 83. The peripheral region 84 includes a region in which the alignment mark 80 of the target object Ma is not located.

Here, in order to easily describe the method of detecting the edge position 81 of the alignment mark 80, an xyz orthogonal coordinate system is utilized. A certain surface on which the alignment mark 80 is formed is defined as an xy plane. A direction perpendicular to the certain surface on which the alignment mark 80 is formed is defined as a z-axis direction. For example, the alignment mark 80 may have a rectangular shape having sides provided in the x-axis direction and the y-axis directions.

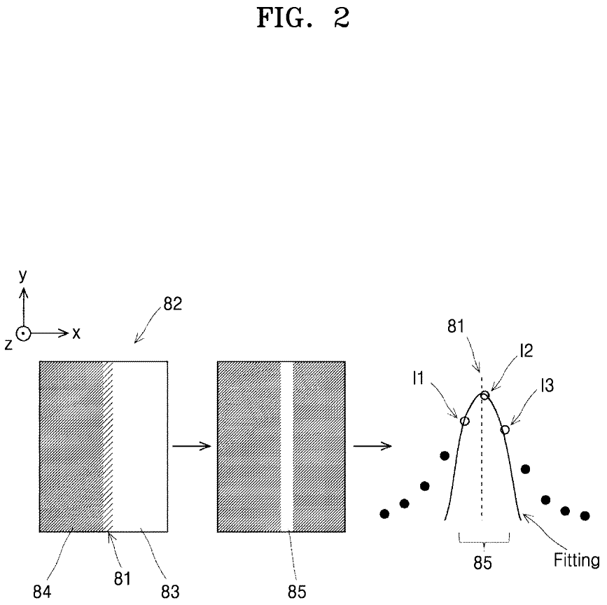

FIG. 2 is a diagram illustrating the ROI of the image including the alignment mark, a region having high intensity of a luminance gradient, and the intensity of the luminance gradient in the method of detecting the edge position of the alignment mark according to some implementations. In FIG. 2, the ROI 82 of the image including the alignment mark 80, a region 85 having high intensity of a luminance gradient, and the intensity of the luminance gradient in the method of detecting the edge position 81 of the alignment mark 80. In FIG. 2, the method of detecting the edge position 81 of the alignment mark 80 calculates the intensity of the luminance gradient in the ROI 82 from a portion of the ROI 82 on the image. For example, the intensity of the luminance gradient may be calculated using a Sobel filter. The region 85 in which the intensity of the luminance gradient is high is located between the peripheral region 84 and the side portion 83. That is, the region 85 having a high luminance gradient includes the edge position 81 of the alignment mark 80.

Next, a luminance profile in the x-axis direction on the image is obtained. The luminance profile represents, for example, a first intensity 11, a second intensity 12, and a third intensity 13 in the x-axis direction. The second intensity 12 is defined as the intensity of the pixel showing the peak in the region 85 in which the intensity of the luminance gradient is high. The first intensity Il and the third intensity 13 represent the intensities of two adjacent pixels with the peak therebetween.

Next, a quadratic function is fitted to the luminance profile that includes the first intensity 11, the second intensity 12, and the third intensity 13. For example, the quadratic function is applied to the luminance profile that includes the intensities of a pixel having the peak intensity of the luminance gradient and surrounding pixels. The vertex of the fitted quadratic function is detected as the edge position 81 of the alignment mark 80.

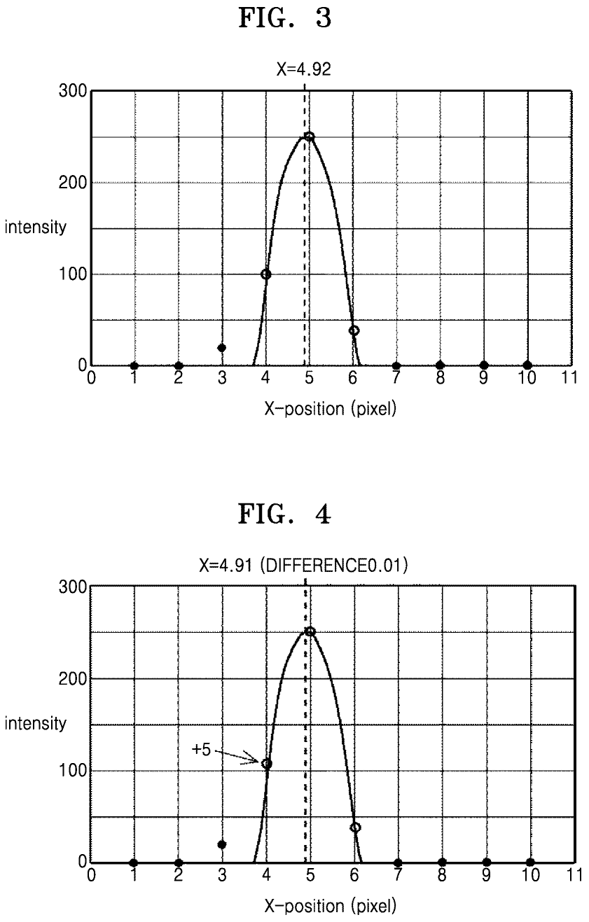

In some implementations, when sharpness of the image is low and the intensity profile of the luminance gradient is gentle, the edge position 81 is likely to become non-uniform due to the influence of noise. FIGS. 3 to 6 are graphs illustrating the intensity of the luminance gradient of the ROI 82 in the method of detecting the edge position 81 of the alignment mark 80. Here, the horizontal axis represents the position on the ROI 82 in the x-axis direction and the vertical axis represents the intensity of the luminance gradient.

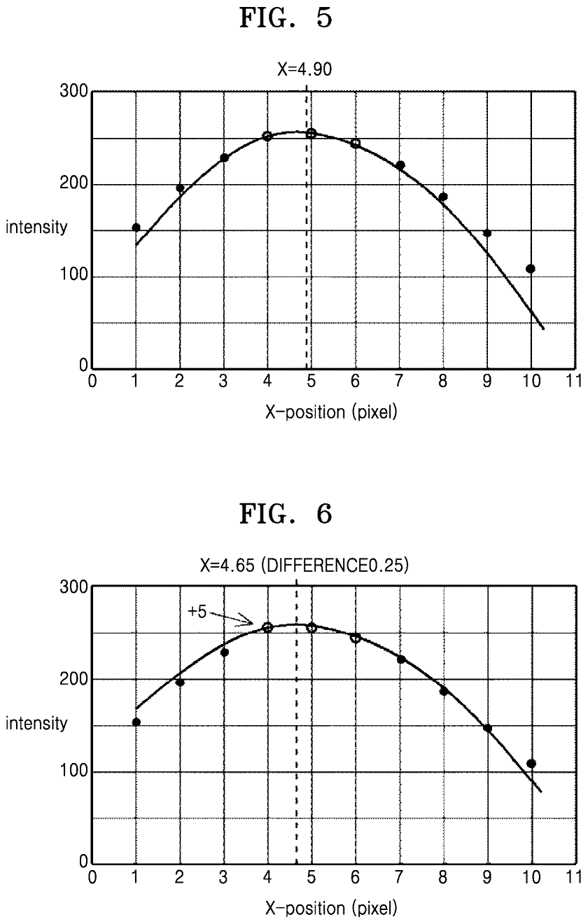

For example, in a profile in which the intensity of the luminance gradient is steep, as shown in FIG. 3, when the intensity of the luminance gradient at position x=4 on the ROI 82 increases by 5 points, as shown in FIG. 4, the edge position 81 of the alignment mark 80 is shifted by 0.01 from x=4.92 to x=4.91. However, in a profile in which the intensity of the luminance gradient is gentle, as shown in FIG. 5, when the intensity of the luminance gradient at position x=4 on the ROI 82 increases by 5 points, as shown in FIG. 6, the edge position 81 of the alignment mark 80 is shifted by 0.25 from x=4.90 to x=4.65. As described above, in the method according to Reference Example 1, the amount of change in the edge position 81 increases due to a change in the intensity of the luminance gradient in the pixel.

Next, an example of a method of detecting an edge position 81 of an alignment mark 80 according to some implementations is described below.

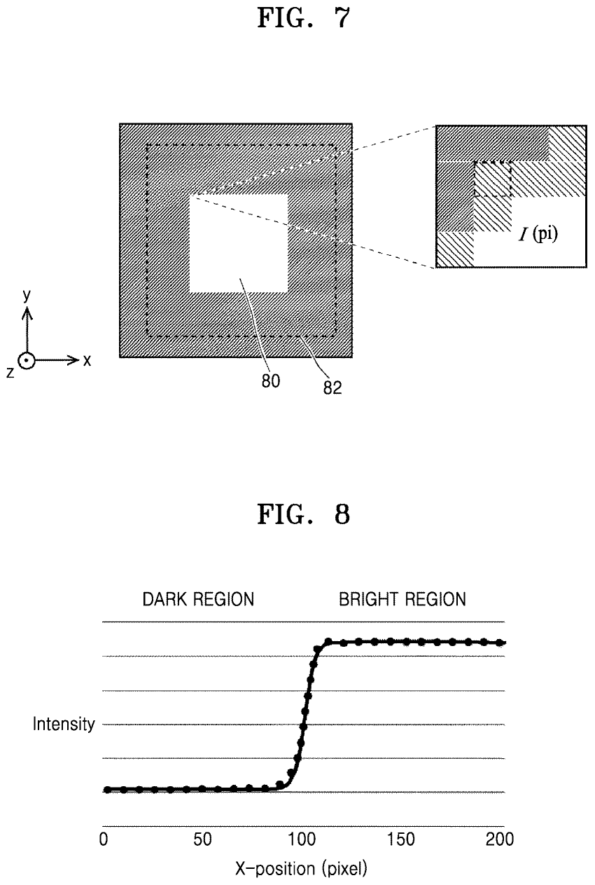

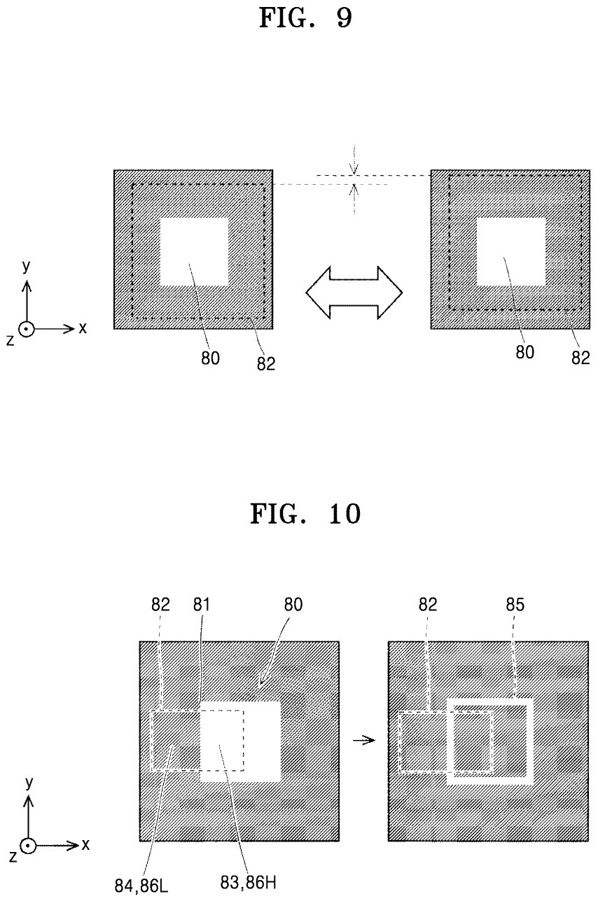

FIG. 7 is a diagram illustrating an example of an ROI of an image that includes an alignment mark in a method of detecting an edge position of the alignment mark according to some implementations. FIG. 8 is a graph illustrating an example of a luminance profile in the method of detecting the edge position of the alignment mark according to some implementations. FIG. 9 is a diagram illustrating an example of misalignment of the ROI of the alignment mark according to some implementations.

In FIG. 7, an ROI 82 of an image includes the alignment mark 80 in the method of detecting the edge position 81 of the alignment mark 80. In FIG. 8, the horizontal axis represents the position on the ROI 82 in the x-axis direction and the vertical axis represents the intensity of the luminance. FIG. 9, misalignment of the ROI 82 of the alignment mark 80 is shown.

In FIG. 7, the method calculates the center of gravity within the ROI 82 using pixels having luminance greater than a threshold. Specifically, the position of the center of gravity is calculated based on a weight value of luminance using Equation (1) below. Accordingly, the method may improve the repeatability of calculating the position of the center of gravity by increasing the number of target pixels to be calculated.

$$[ Equation 1 ]$$

$${p}^{l} = \frac{1}{\sum I ( {p}_{i}^{l} )} \sum {p}_{i}^{l} I ( {p}_{i}^{l} ) ( I ( {p}_{i}^{l} ) > T ) \qquad ( 1 )$$

Here, p^{l} represents the position of the center of gravity, I represents the intensity of luminance, I(pᵢ^{l}) represents the intensity of luminance at pᵢ^{l}, and T represents the threshold.

In FIG. 8, when the position of the center of gravity is calculated using only bright regions including pixels having luminance greater than or equal to the threshold, only pixels having luminance greater than or equal to threshold are used for calculation. Also, when all pixels in the ROI 82 are used without applying the threshold of luminance, the target pixel to be calculated changes as the position of the ROI 82 is shifted even by one pixel, as shown in FIG. 9. Accordingly, the result of the edge position 81 becomes significantly non-uniform. Also, the position of the ROI 82 may be set by roughly recognizing the alignment mark 80. Furthermore, the edge position 81 on the image is usually blurred. Accordingly, it is difficult to obtain a result in which even one pixel is not misaligned by template matching.

Next, an example of a method of detecting an edge position 81 of an alignment mark 80 according to some implementations is described below.

FIG. 10 is a diagram illustrating an example of an alignment mark and the intensity of a luminance gradient in a method of detecting an edge position of the alignment mark according to some implementations. FIG. 11 is a graph illustrating the intensity of the luminance gradient of the ROI in the method of detecting the edge position of the alignment mark according to some implementations.

In FIG. 10, the alignment mark 80 and the intensity of a luminance gradient in the method of detecting the edge position 81 of the alignment mark 80 according to some implementations is shown. In FIG. 11, the intensity of the luminance gradient of the ROI 82 in the method of detecting the edge position 81 of the alignment mark 80 according to some implementations is shown. Here, the horizontal axis represents the position on the ROI 82 in the x-axis direction and the vertical axis represents the intensity of the luminance gradient.

In FIG. 10, the method fits a certain function, such as a Gaussian function, to the profile of the intensity of the luminance gradient in the ROI 82 including a side portion 83 and a peripheral region 84. Accordingly, the method detects the edge position 81 of the alignment mark 80. However, as shown in FIG. 11, the intensity of the luminance gradient in a dark region is slightly different from the intensity of the luminance in a bright region. That is, there is a difference in the amounts of noise between a high-luminance region 86H and a low-luminance region 86L. Accordingly, the precision deteriorates when fitting a function having symmetry. The difference in the amounts of noise between the high-luminance region 86H and the low-luminance region 86L is considered to be due to photon shot noise in a fitting error expressed by Equation (2) below.

$$[ Equation 2 ]$$

$${σ}_{eff} = \sqrt{{σ}_{p}^{2} + {σ}_{R}^{2} + {σ}_{S}^{2}} \qquad ( 2 )$$

Here, the first term (σ_{D}) in the root represents dark shot noise. The second term (σ_{R}) represents read noise. The third term (σ_{S}) is photon shot noise expressed by Equation (3) below.

$$\begin{matrix}[ Equation 3 ] & \\ {θ}_{S} = \sqrt{( QE ) N t} & ( 3 )\end{matrix}$$

Here, QE represents quantum efficiency (constant in the image), N represents a photon flux density (dark<light), and t represents an exposure time (constant in the image).

Accordingly, there is a difference in levels of flat regions between the high-luminance region 86H and the low-luminance region 86L, and thus, the fitting error of the Gaussian function increases.

Next, an example of a method of detecting an edge position 81 of an alignment mark 80 according to some implementations is described below.

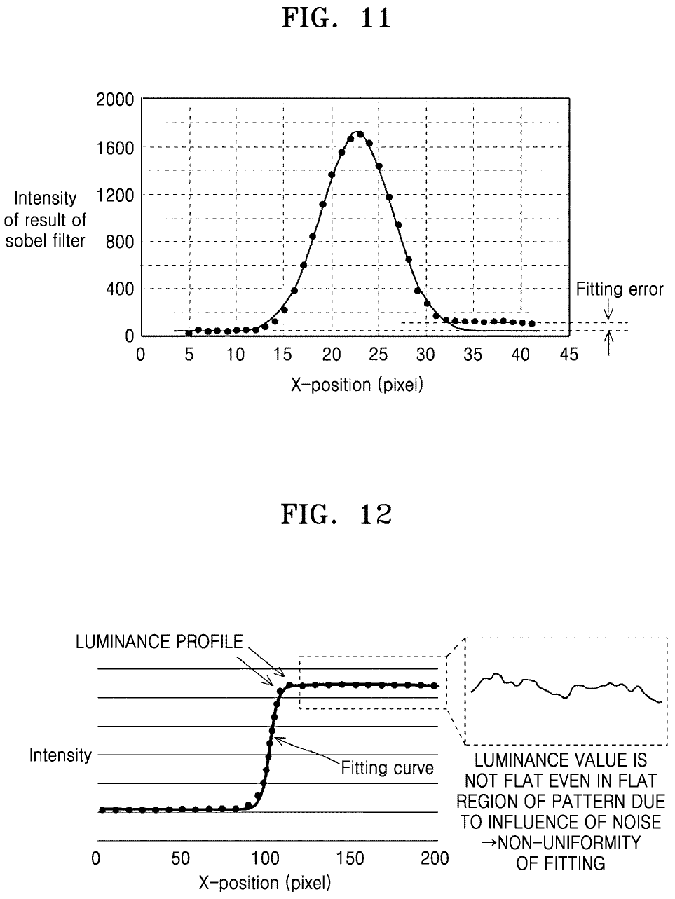

FIG. 12 is a graph illustrating an example of a luminance profile of an ROI in a method of detecting an edge position of an alignment mark according to some implementations. In FIG. 12, a luminance profile of an ROI 82 in the method of detecting the edge position 81 of the alignment mark 80 is shown. Here, the horizontal axis represents the position on the ROI 82 in the x-axis direction and the vertical axis represents the intensity of the luminance. In FIG. 12, the position on the ROI 82 in the x-axis direction may represent the number of a pixel in the x-axis. For example, the 100^{th} position on the x-axis represents the edge position 81. The position in the (−)x-axis direction from the 100th position represents the position of a peripheral region 84 of the alignment mark 80 and the position in the (+) x-axis direction from the 100^{th} position represents the position of a side portion 83 of the alignment mark 80.

In FIG. 12, the edge position 81 is obtained by fitting a sigmoid function, as shown in Equation (4) below, to the luminance profile in the ROI 82 including the side portion 83 and the peripheral region 84.

$$[ Equation 4 ]$$

$$f ( x ) = \frac{1}{1 + exp ( - a x )} \qquad ( 4 )$$

Here, a represents curvature. However, the luminance is not flat even in a flat region of the side portion 83 due to the influence of noise of the luminance profile. Accordingly, non-uniformity may occur when fitting the fitting function to the flat region of a pattern of the side portion 83. Also, when the amount of blurring of the alignment mark 80 is large or the alignment mark 80 is small, the luminance profile having a sufficient number of pixels may not be acquired, resulting in deterioration in precision.

Next, an examples of a mounting device and an example of a method of detecting an edge position 81 of an alignment mark 80 according to some implementations are described below.

In the method of detecting an edge position 81 of an alignment mark 80, a fitting function including a sigmoid curve as shown in Equation (5) below is fitted to a luminance profile.

$$[ Equation 5 ]$$

$$f ( x ) = ( \frac{1}{1 + exp ( - \frac{x - {μ}_{1}}{{a}_{1}} )} + \frac{1}{1 + exp ( - \frac{x - {μ}_{2}}{{a}_{2}} )} ) b + c \qquad ( 5 )$$

Here, μ₁ and μ₂ represent inflection points, a₁ and a₂ represent curvatures, and b and c represent constants.

In the method of detecting the edge position 81, according to some implementations, repeatability of detection of the edge position 81 is improved by optimizing parameters at the time of fitting. Specifically, pixels in non-edge regions, which are located in the high-luminance region 86H and the low-luminance region 86L including flat regions of the sigmoid curve, are expanded within a range that does not deviate from the shape of the fitting function and the luminance profile. Here, the calculation time for detecting the edge position 81 is set to cover the maximum range of the ROI 82 within an allowable range. Accordingly, the non-uniformity of individual pixels may be suppressed when detecting the edge position 81 of the alignment mark 80.

First, the mounting device, according to some implementations, is described below. The mounting device aligns positions of upper and lower target objects with each other using an upper and lower dual field-of-view (FOV) optical system. Also, this mounting device mounts the upper target object on the lower target object. Specifically, for example, the mounting device detects center positions of alignment marks 80 by detecting edge positions 81 of the alignment marks 80. Then, the mounting device aligns the positions of target objects Ma and Mb and bond the target objects Ma and Mb to each other, using the detection results of the edge positions 81 and the center positions of the alignment marks 80.

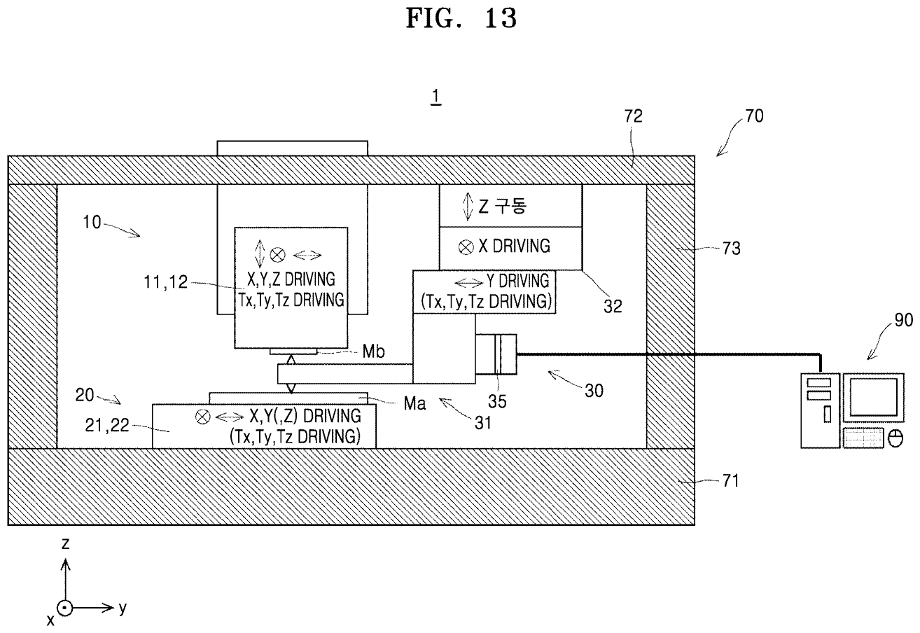

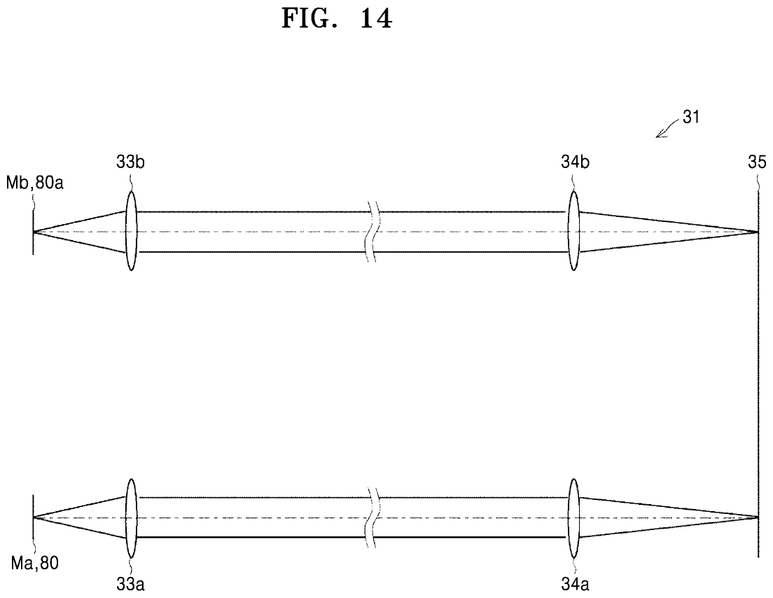

FIG. 13 is a configuration diagram illustrating an example of a mounting device according to some implementations. In FIG. 13, the mounting device 1 includes a bonding head 10, a bonding stage 20, an upper and lower dual FOV optical system 30, and a processing device 90. Each of the components of the mounting device 1 other than the processing device 90 may be placed on a base frame 70. Also, the processing device 90 may also be placed on the base frame 70.

The base frame 70 includes a base structure of the mounting device 1. The base frame 70 has, for example, a rectangular parallelepiped shape having a base plate 71, an upper frame 72, and a side frame 73. The side frame 73 supports the upper frame 72 on the base plate 71. Also, the base frame 70 may have other shapes as long as each of the components of the mounting device 1 may be arranged thereon.

Here, in order to easily describe the mounting device 1, an XYZ orthogonal coordinate system is utilized. For example, a direction perpendicular to the upper surface of the base plate 71 is defined as a Z-axis direction and two directions perpendicular to each other within a plane parallel to the upper surface of the base plate 71 are respectively defined as an X-axis direction and a Y-axis direction. The (+)Z-axis direction is defined as an upward direction and the (−)Z-axis direction is defined as a downward direction. Also, the upward and downward directions are defined for the convenience of description of the mounting device 1 and are not intended to limit the direction in which the mounting device 1 is actually placed when used. In the xyz orthogonal coordinate system in which the certain surface of the target object Ma, on which the alignment mark 80 described above is located, is defined as the xy plane, the certain surface of the target object Ma and the upper surface of the base plate 71 coincide with each other when parallel to each other. Hereinafter, each of the components of the mounting device 1 is described below.

### Bonding Head

The bonding head 10 holds and supports the target object Mb. The target object Mb includes a member bonded to the target object Ma. The target object Mb includes a member, such as a die. Also, the target object Mb is not limited to the die but also includes members, such as wafers, chips, and interposers. The bonding head 10 has a head 11 and a driving mechanism 12.

The head 11 holds and supports the target object Mb. For example, the head 11 may suction and grip the target object Mb. The driving mechanism 12 is fixed to the upper frame 72. The driving mechanism 12 moves the head 11 in parallel in the X-axis direction, the Y-axis direction, and the Z-axis direction. Also, the driving mechanism 12 may rotate the head 11 about axes that rotate around the X-axis, Y-axis, and Z-axis. As described above, the bonding head 10 may function as a bonding tool.

Specifically, the driving mechanism 12 may have parallel movement axes that function as a bonding tool and move the head 11 in parallel in the X-axis, Y-axis, and Z-axis directions and rotation axes Tx, Ty and Tz that rotate the head 11 around each of axes. Accordingly, the bonding head 10 adjusts the relative position and parallelism between the target object Mb (or referred to as the upper target object Mb) and the target object Ma (or referred to as the lower target object Ma). Also, the bonding head 10 may bond the target object Ma and the target object Mb to each other.

### Bonding Stage

The bonding stage 20 holds and supports the target object Ma. The target object Ma includes a member bonded to the target object Mb. The target object Ma includes a member, such as a wafer. Also, the target object Ma is not limited to a wafer but may also include members, such as a chip, a die, or an interposer. The target object Ma may include a member that becomes the lowermost layer when constituting a stack body. The bonding stage 20 has a stage 21 and a driving mechanism 22.

The stage 21 holds and supports the target object Ma. For example, the stage 21 may suction and grip the target object Ma. The driving mechanism 22 is fixed to the base plate 71. The driving mechanism 22 moves the stage 21 in parallel in the X-axis direction and the Y-axis direction. Accordingly, the bonding stage 20 may move the target object Ma in the X-axis direction and the Y-axis direction. In addition, the driving mechanism 22 may move the stage 21 in parallel in the Z-axis direction or rotate the stage 21 about axes that rotate around the X-axis, Y-axis, and Z-axis.

Instead of the bonding head 10 or in addition to the bonding head 10, the bonding stage 20 may have parallel movement axes that function as a bonding tool and move the stage 21 in parallel in the X-axis, Y-axis, and Z-axis directions and rotation axes Tx, Ty and Tz that rotate the stage 21 around each of axes. Accordingly, the bonding stage 20 may adjust the relative position and parallelism between the upper target object Mb and the lower target object Ma. Also, the bonding stage 20 may bond the target object Ma and the target object Mb to each other.

Accordingly, at least one of the bonding head 10 and the bonding stage 20 functions as a bonding unit for bonding the target object Mb to the target object Ma. For example, the mounting device 1 is provided with the bonding unit. The bonding unit includes at least one of the bonding head 10 and the bonding stage 20.

### Upper and Lower Dual FOV Optical System

The upper and lower dual FOV optical system 30 is inserted between the target object Ma and the target object Mb and captures images of the target object Ma and the target object Mb. For example, the upper and lower dual FOV optical system 30 may simultaneously capture the images of the target object Ma and the target object Mb. Here, the upper and lower dual FOV optical system 30 is inserted between the upper target object Mb and the lower target object Ma and captures the images of the upper target object Mb and the lower target object Ma, but the embodiment is not limited thereto. For example, the upper and lower dual FOV optical system 30 is inserted between a left target object and a right target object and captures images of the left target object and the right target object. In other words, the upper and lower dual FOV optical system 30 may capture images in two opposite directions, such as the left and right directions, as well as the up and down directions. Also, the upper and lower dual FOV optical system 30 may simultaneously capture images in two opposite directions, such as the left and right directions. Accordingly, the upper and lower dual FOV optical system 30 may be simply referred to as a dual FOV optical system.

The upper and lower dual FOV optical system 30 has an optical unit 31 and a driving mechanism 32. The driving mechanism 32 is fixed to the base frame 70. The driving mechanism 32 is fixed to, for example, the upper frame 72. The driving mechanism 32 may move the optical unit 31 in parallel in each of the X-axis, Y-axis, and Z-axis directions. Also, the driving mechanism 32 may rotate the optical unit 31 about axes that rotate around the X-axis, Y-axis, and Z-axis. The driving mechanism 32 moves the optical unit 31 between a plurality of alignment marks 80. Also, the driving mechanism 32 moves the optical unit 31 in the Z-axis direction and adjusts the focus of the optical unit 31. In addition, the driving mechanism 32 may adjust the inclination of the upper and lower dual FOV optical system 30.

### Optical Unit of Upper and Lower Dual FOV Optical System

FIG. 14 is a configuration diagram illustrating an example of an optical unit of an upper and lower dual field-of-view (FOV) optical system in the mounting device according to some implementations. In FIG. 14 the optical unit 31 of the upper and lower dual FOV optical system 30 may be in the mounting device 1. As shown in FIG. 14, the optical unit 31 of the upper and lower dual FOV optical system 30 has a plurality of optical members, a lighting tool, and an image sensor 35 such as a camera. The plurality of optical members include, for example, an objective lens 33a, an objective lens 33b, a tube lens 34a, and a tube lens 34b. An image of the upper target object Mb is formed on the image sensor 35 via the objective lens 33b and the tube lens 34b. An image of the lower target object Ma is formed on the image sensor 35 via the objective lens 33a and the tube lens 34a.

For example, the image sensor 35 may simultaneously capture an image of an alignment mark 80 formed on the target object Ma and an image of an alignment mark 80a formed on the target object Mb. The plurality of optical members respectively form images of the alignment marks 80 and 80a on the image sensor 35. When the alignment mark 80 of the target object Ma is defined as the first alignment mark and the alignment mark 80a of the target object Mb is defined as the second alignment mark, the upper and lower dual FOV optical system 30 has a single image sensor that captures images of the first alignment mark and the second alignment mark. Also, as another configuration, a common objective lens and a common tube lens may be used for both components forming an image of the upper target object Mb on the image sensor 35 and components forming an image of the lower target object Ma on the image sensor 35.

FIG. 14 shows that both target objects Ma and Mb are on the left side. However, actually, the target objects Ma and Mb are arranged to face each other with the optical unit 31 therebetween as shown in FIG. 13. Accordingly, some optical members are omitted in FIG. 14. For example, the bending of an optical path is minimally illustrated in FIG. 14 to describe the upper and lower dual FOV optical system 30. Actually, the optical path may be appropriately bent into a flat mirror for assembly into a compact casing. The optical unit 31 may further include a casing for fixing the plurality of optical members and a lighting tool for illuminating the alignment marks 80 and 80a.

### Alignment Mark

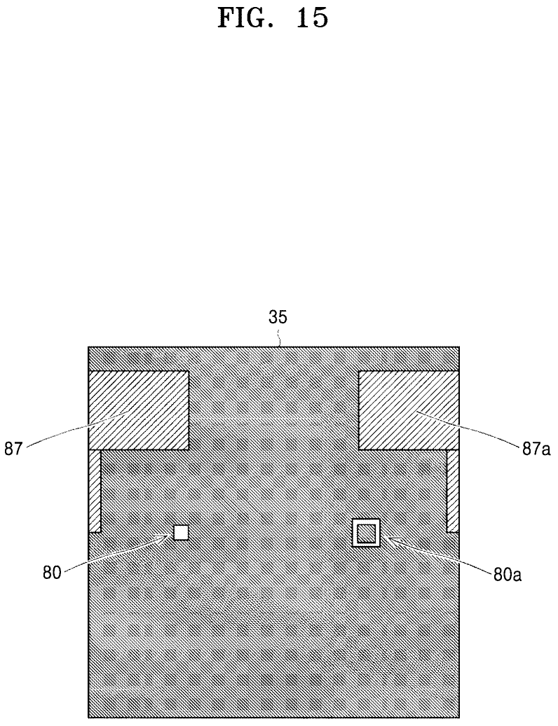

FIG. 15 is a diagram illustrating an example of an image of an alignment mark captured by an image sensor in the mounting device according to some implementations. In FIG. 15, the alignment marks 80 and 80a are captured by the image sensor 35 in the mounting device 1. As shown in FIG. 15, for example, the image sensor 35 captures the images of the alignment mark 80 formed on the target object Ma and the alignment mark 80a formed on the target object Mb. The plurality of optical members respectively form images of the alignment marks 80 and 80a on the image sensor 35. Also, as described above for another implementation, a common objective lens and a common tube lens may be used for both components forming an image of the upper target object Mb on the image sensor 35 and components forming an image of the lower target object Ma on the image sensor 35.

A pair of alignment marks 80 and 80a are vertically and respectively arranged on the target objects Ma and Mb. When the target objects Ma and Mb are large relative to the field of view, the optical unit 31 moves to a plurality of positions on the target objects Ma and Mb and recognizes the pair of alignment marks 80 and 80a at each of the positions. In order to minimize the misalignment of the alignment marks 80 and 80a at one or more sets of positions, at least one of the bonding head 10 and the bonding stage 20 functioning as a bonding tool adjusts at least one of the relative position and parallelism between the upper target object Mb and the lower target object Ma on the basis of the images obtained by the image sensor 35 and bond the upper target object Mb and the lower target object Ma to each other.

The captured image of the alignment marks 80 and 80a may include a region corresponding to another mark 87. The region corresponding to another mark 87 includes, for example, other alignment marks and/or circuit patterns formed on the target objects Ma and Mb.

### Processing Device

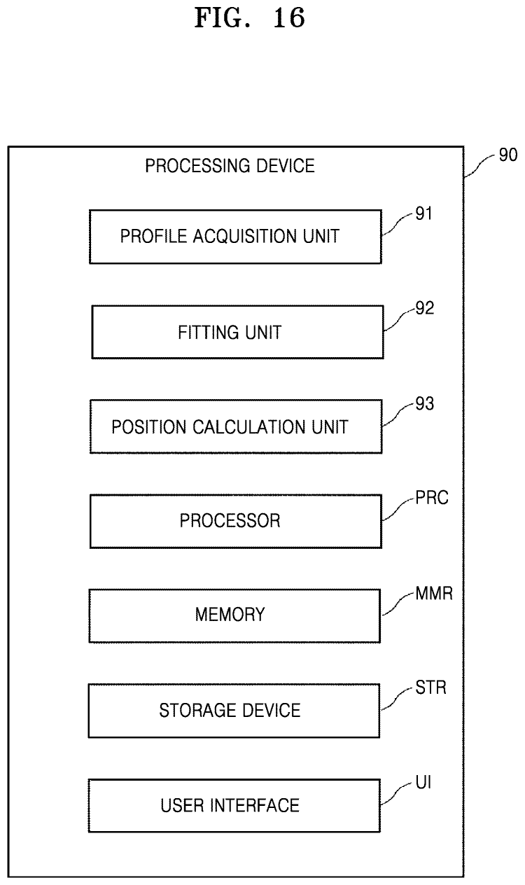

FIG. 16 is a block diagram illustrating an example of a processing device in the mounting device according to some implementations. In FIG. 16, the processing device 90 in included in the mounting device 1. As shown in FIG. 16, the processing device 90 is provided with a profile acquisition unit 91, a fitting unit 92, and a position calculation unit 93. The processing device 90 may include an information processing device, such as a microcomputer, a personal computer, and a server. The processing device 90 may further include a processor PRC, a memory MMR, a storage device STR, and a user interface UI.

The storage device STR may store processing, which is performed by each component of the processing device 90, as a program. Also, the processor PRC makes the memory MMR read a program from the storage device STR and executes the program. Accordingly, the processor PRC allows components of the processing device 90, such as the profile acquisition unit 91, the fitting unit 92, and the position calculation unit 93, to perform functions thereof. The user interface UI may include input devices, such as a keyboard, mouse, and an image capturing unit, and output devices, such as a display, a printer, and a speaker.

Each of the components of the processing device 90 may be provided as dedicated hardware. In addition, some or all of the components may be provided as general-purpose or dedicated circuitry, the processor PRC, or a combination thereof. These components may be configured by a single chip or a plurality of chips connected via a bus. Some or all of the components may be configured by a combination of the above-described circuits and programs. In addition, a central processing unit (CPU), a graphics processing unit (GPU), a field-programmable gate array (FPGA), and/or a quantum processor (a quantum computer control chip) may be used as the processor PRC.

Also, when some or all of the components of the processing device 90 are configured by a plurality of information processing devices, circuits, or the like, the plurality of information processing devices, circuits, or the like may be arranged centrally or in a distributed manner. For example, the information processing devices, circuits, or the like may be connected to each other via a communication network by a client server system, a cloud computing system, or the like. Also, the functions of the processing device 90 may be provided in a software as a service (Saas) format.

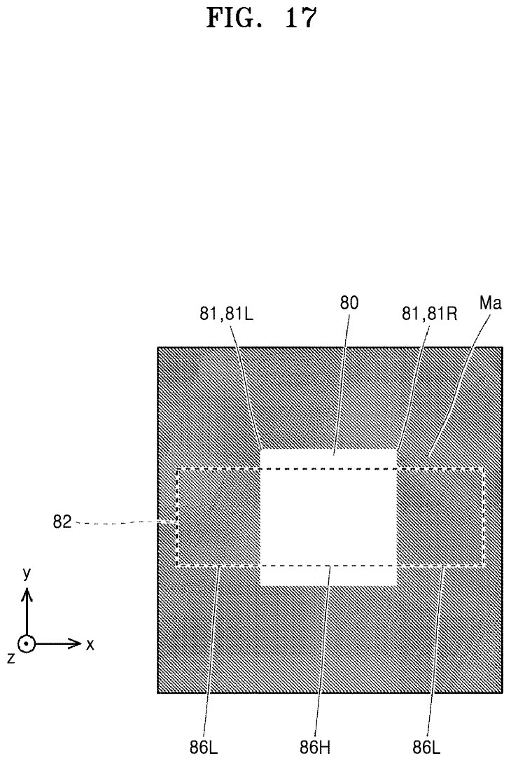

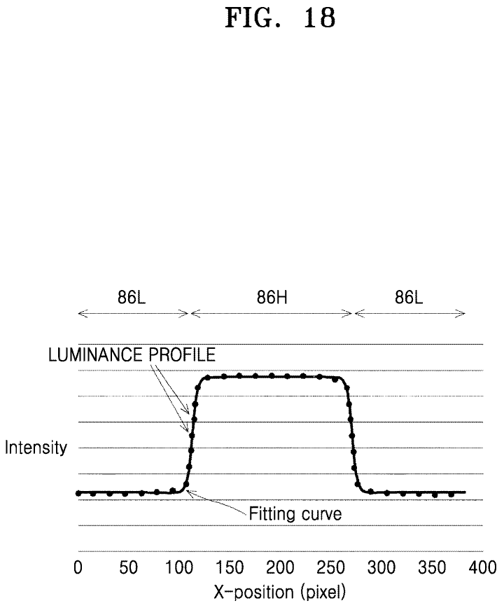

FIG. 17 is a diagram illustrating an example of a captured image of a region including an alignment mark formed on an object to be bonded in the mounting device according to some implementations. In FIG. 17, a captured image of a region including the alignment mark 80 is formed on the target object Ma in the mounting device 1. As shown in FIG. 17, the profile acquisition unit 91 may obtain the ROI 82, which includes a high-luminance region 86H and a plurality of low-luminance regions 86L, from the captured image of the region including the alignment mark 80 formed on the target object Ma. The high-luminance region 86H includes a region corresponding to the alignment mark 80 on the image. The plurality of low-luminance regions 86L are arranged on both sides of the alignment mark 80 in the x-axis direction. The plurality of low-luminance regions 86L may include, for example, regions other than the alignment mark 80 of the target object Ma. Each of the low-luminance regions 86L has lower luminance than the high-luminance region 86H. The plurality of low-luminance regions 86L are arranged with the high-luminance region 86H that is inserted therebetween from both sides in the x-axis direction. Also, the x-axis direction may be replaced with the y-axis direction. Even in the following description, the x-axis direction may be replaced with the y-axis direction in some cases. An edge position 81L is located between the high-luminance region 86H and the low-luminance region 86L on one side of the high-luminance region 86H and an edge position 81R is located between the high-luminance region 86H and the low-luminance region 86L on another side of the high-luminance region 86H. For example, on the basis of the captured image of the region including the alignment mark 80 formed on the target object Ma, the profile acquisition unit 91 obtains a luminance profile formed in one direction of the ROI 82 including the first region, the second region, and the third region arranged in the one direction on the image. The second region corresponds to the alignment mark 80. The first region and the third region have a difference in luminance level from the second region.

FIG. 18 is a graph illustrating an example of a luminance profile and a fitting function in the mounting device according to some implementations. In FIG. 18, a luminance profile and a fitting function are included in the mounting device 1. Here, the horizontal axis represents the position on the ROI 82 in the x-axis direction and the vertical axis represents the intensity of luminance. As shown in FIG. 18, the profile acquisition unit 91 obtains the luminance profile of the ROI 82 in the x-axis direction, on the basis of the captured image of the region including the alignment mark 80 formed on the target object Ma.

The fitting unit 92 fits a fitting function, which includes a sigmoid function having an inflection point and a curvature, to the luminance profile. Then, the fitting unit 92 sets inflection points to the edge position 81L and the edge position 81R of the alignment mark 80. Here, the fitting function includes Equation (5) described above.

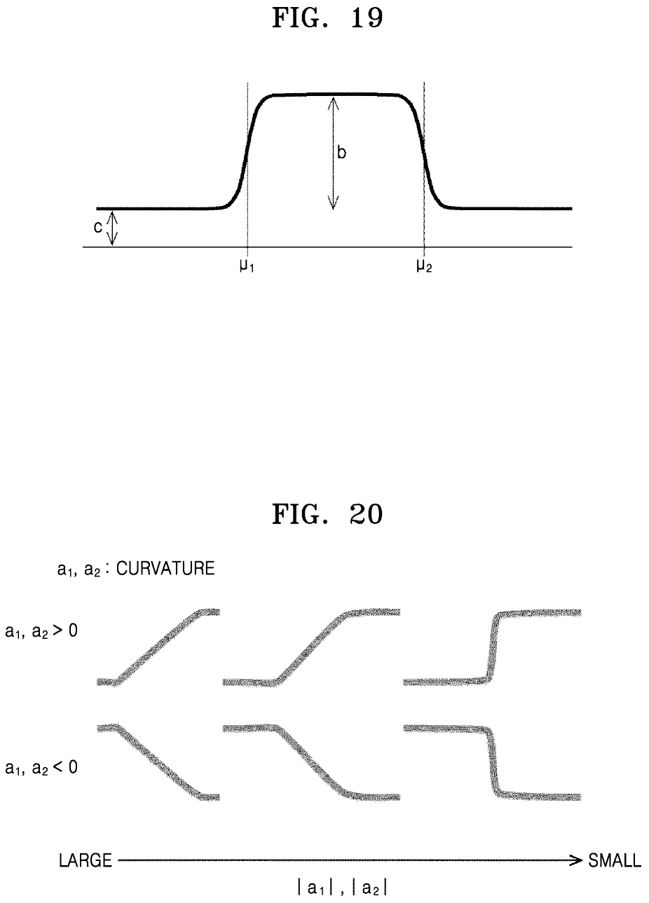

FIG. 19 is a graph illustrating the fitting function in the mounting device according to some implementations. In FIG. 19, the fitting function is included in the mounting device 1. Here, the horizontal axis represents the position on the ROI 82 in the x-axis direction and the vertical axis represents the intensity of luminance.

FIG. 20 is a diagram illustrating examples of curvatures depending on coefficients of the fitting function in the mounting device according to some implementations. In FIG. 20, curvatures depending on coefficients of the fitting function are included in the mounting device 1. As shown in FIGS. 19 and 20, μ₁ and μ₂ represent inflection points, a₁ and a₂ represent curvatures and signs (positive and/or negative), and b and c represent constants. In addition, the texts representing the curvatures of the denominator of exp( ) in the above equation are indicated as a₁ and a₂ in this specification due to font circumstances.

When a₁ and a₂ are positive, the fitting function increases. When a₁ and a₂ are negative, the fitting function decreases. As the absolute values of a₁ and a₂ increase, the level difference between the low-luminance region 86L and the high-luminance region 86H becomes gentler. As the absolute values of a₁ and a₂ decreases, the level difference between the low-luminance region 86L and the high-luminance region 86H becomes steeper.

The ROI 82 includes a first edge portion having an edge of the alignment mark 80 between the high-luminance region 86H and the low-luminance region 86L on one side of the high-luminance region 86H and a second edge portion having an edge of the alignment mark 80 between the high-luminance region 86H and the low-luminance region 86L on another side of the high-luminance region 86H. The fitting function includes a first sigmoid function having a first inflection point μ₁ and a first curvature a₁ of the first edge portion and a second sigmoid function having a second inflection point μ₂ and a second curvature a₂ of the second edge portion.

The fitting unit 92 estimates μ₁, μ₂, a₁, a₂, b, and c so that errors between the intensities at points on the luminance profile and the values of the fitting function are minimized. The initial values thereof use the following values. For example, μ₁ uses, as the initial value, the position at which the output value obtained by applying the Sobel filter to the luminance profile is maximum. M₂ uses, as the initial value, the position at which the output value obtained by applying the Sobel filter to the luminance profile is minimum. a₁, a₂, b, and c use, as initial values, the results of previously captured images. The estimation method uses a downhill simplex method, but there are no limiting factors.

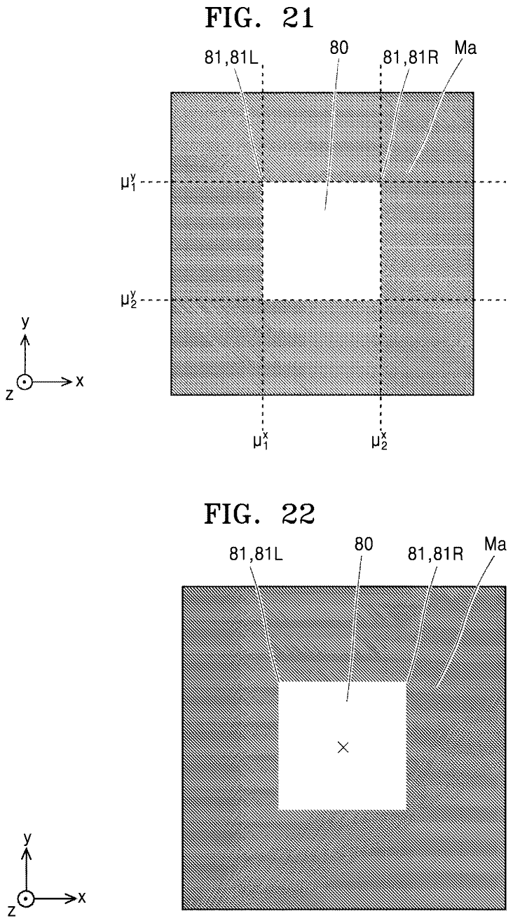

FIG. 21 is a diagram illustrating examples of edge positions detected by the mounting device according to some implementations. In FIG. 21, edge positions 81 may be detected by the mounting device 1. As shown in FIG. 21, the edge position 81L of the alignment mark 80 is set to μ₁^{x} in the x-axis direction, and the edge position 81R of the alignment mark 80 is set to μ₂^{x} in the x-axis direction. The same processing is also performed in the y-axis direction. For example, the two edge positions 81 of the alignment mark 80 in the y-axis direction are calculated from μ₁^{y} and μ₂^{y} in the y-axis direction.

FIG. 22 is a diagram illustrating an example of a center position calculated by a position calculation unit in the mounting device according to some implementations. In FIG. 22, a center position may be calculated by the position calculation unit 93 in the mounting device 1. As shown in FIG. 22, the position calculation unit 93 calculates the center position of the alignment mark 80 on the basis of the detected edge position 81L and edge position 81R. For example, the position calculation unit 93 calculates the center position of the alignment mark 80 in the x-axis direction from Equation (6) below. Also, the position calculation unit 93 calculates the center position of the alignment mark 80 in the y-axis direction from Equation (7) below. Specifically, for example, the high-luminance region 86H corresponding to the alignment mark 80 may have a quadrangular shape having sides in one direction and sides in another direction intersecting with the one direction. The position calculation unit 93 calculates a first center position of the alignment mark 80 in one direction on the basis of the edge position 81 detected in the one direction and calculates a second center position of the alignment mark 80 in another direction on the basis of the edge position 81 detected in another direction.

$$[ Equation 6 ]$$

$$x = \frac{{μ}_{1}^{x} + {μ}_{2}^{x}}{2} \qquad ( 6 )$$

$$[ Equation 7 ]$$

$$y = \frac{{μ}_{1}^{y} + {μ}_{2}^{y}}{2} \qquad ( 7 )$$

Here, x represents the center position of the alignment mark 80 in the x-axis direction, y represents the center position of the alignment mark 80 in the y-axis direction, μ₁^{x} and μ₂^{x} represent the edge positions 81 of the alignment mark 80 in the x-axis direction, and μ₁^{y} and μ₂^{y} represent the edge positions 81 of the alignment mark 80 in the y-axis direction.

The bonding unit bonds the target object Mb to the target object Ma using the calculated center positions of the alignment mark 80. The bonding unit may bond the target object Mb to the target object Ma using at least one of the edge position 81L and the edge position 81R of the alignment mark 80. The bonding unit includes at least one of the bonding head 10 and the bonding stage 20.

### Mounting Method

Next, an example of a mounting method using the mounting device 1 according to some implementations is described below.

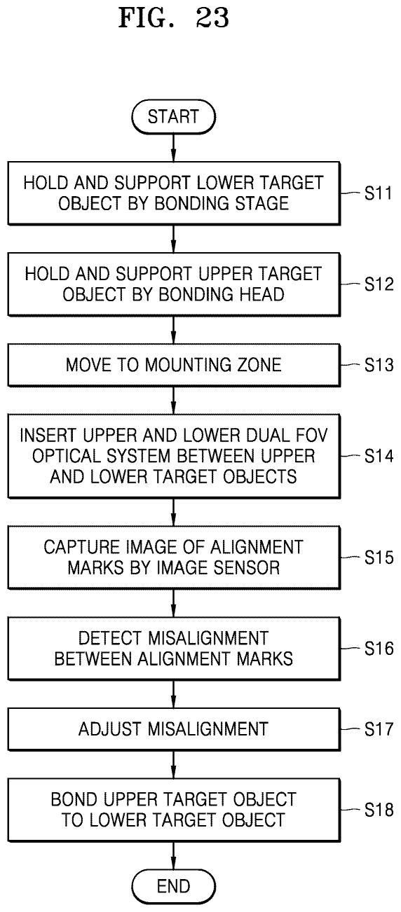

FIG. 23 is a flowchart illustrating an example of a mounting method using the mounting device according to some implementations. In FIG. 23, a mounting method may use the mounting device 1.

As shown in operation S11 of FIG. 23, the lower target object Ma is held and supported by the bonding stage 20.

Next, as shown in operation S12, the upper target object Mb is held and supported by the bonding head 10. For example, a member supply unit, such as a die lifter, is disposed on the bonding stage 20. Accordingly, as the bonding stage 20 moves, the die lifter is positioned below the bonding head 10. Then, the head 11 of the bonding head 10 may grip the upper target object Mb from the die lifter.

Next, as shown in operation S13, the lower target object Ma is moved to a mounting zone. Specifically, as the bonding stage 20 moves, the mounting zone of the lower target object Ma is moved below the bonding head 10.

Next, as shown in operation S14, the upper and lower dual FOV optical system 30 is inserted between the upper target object Mb and the lower target object Ma. Next, as shown in operation S15, images of the target objects Ma and Mb are captured by the image sensor 35 of the upper and lower dual FOV optical system 30. The images of the target objects Ma and Mb may be simultaneously captured. Specifically, the alignment marks 80 and 80a are captured inside the field of view of the upper and lower dual FOV optical system 30 inserted between the target objects Ma and Mb. Accordingly, the image sensor 35 captures the image including the alignment marks 80 and 80a. As a result, the image of the alignment mark 80 formed on the target object Ma and the alignment mark 80a formed on the target object Mb is captured by a single image sensor 35 in the upper and lower dual FOV optical system 30.

Next, as shown in operation S16, misalignment between the alignment mark 80 at a higher level (or referred to as the upper alignment mark 80) and the alignment mark 80a at a lower level (or referred to as the lower alignment mark 80a) is detected. Specifically, the center positions of the alignment marks 80 and 80a reflected from the obtained image are each detected according to detection flow described below. The misalignment may be detected by a separation distance between the upper and lower alignment marks 80 and 80a. The separation distance may be calculated based on distances of the upper and lower alignment marks 80 and 80a in the x-axis direction and the y-axis direction. That is, the separation distance may be calculated based on the horizontal separation distance of the upper and lower alignment marks 80 and 80a.

Next, as shown in operation S17, the misalignment is adjusted. For example, at least one of the bonding head 10 and the bonding stage 20 adjusts the relative positions between the target object Ma and the target object Mb, using the center positions detected based on the image of the alignment marks 80 and 80a obtained by the image sensor 35.

Next, as shown in operation S18, the upper target object Mb and the lower target object Ma are bonded to each other. For example, the bonding head 10 as a bonding tool is lowered to press and bond the upper target object Mb to the lower target object Ma. Accordingly, the target object Mb is bonded to the target object Ma using the detected edge position 81.

Next, an example of a method of detecting the misalignment of the alignment mark 80 in above operation S16 is described below, in which the misalignment between the alignment marks 80 is detected by detecting the center positions of the alignment marks 80.

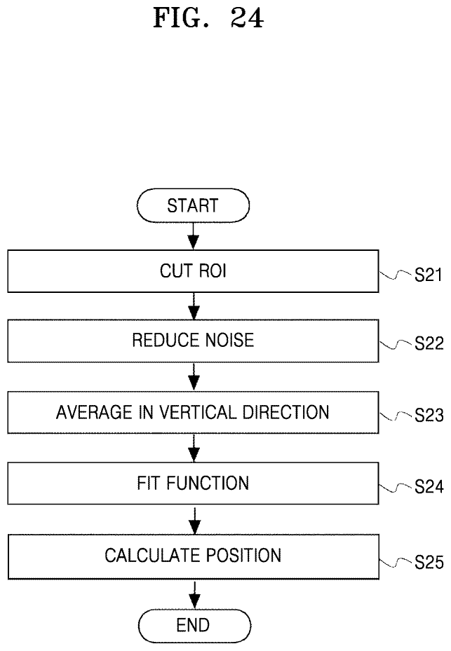

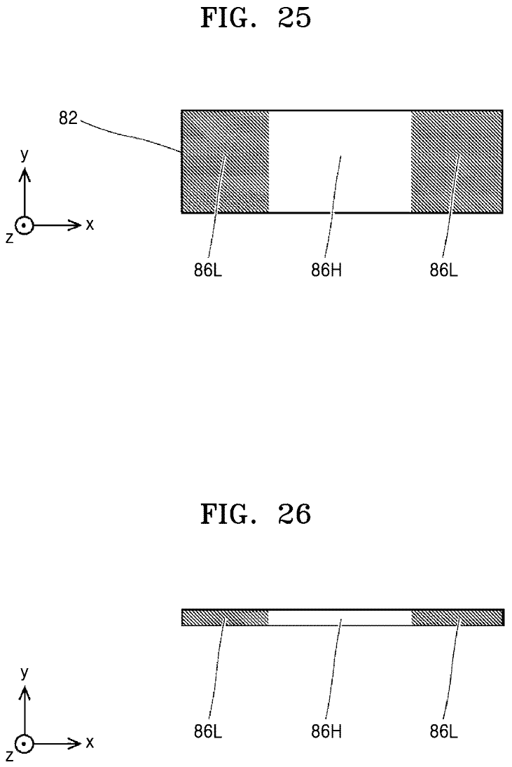

FIG. 24 is a flowchart illustrating an example of a method of detecting the center position of the alignment mark, according to some implementations. FIG. 25 is a diagram illustrating an examples of an ROI that is cut out by a profile acquisition unit in the mounting method according to some implementations. In FIG. 25, the ROI 82 is cut out by the profile acquisition unit 91. FIG. 26 is a diagram illustrating examples of data that is obtained by averaging the luminance of ROI in the mounting method according to some implementations. In FIG. 26, data is obtained by averaging the luminance of the ROI 82.

As shown in operation S21 of FIGS. 24 and 25, the profile acquisition unit 91 cuts out the ROI 82 from the image including the alignment mark 80. The ROI 82 includes a high-luminance region 86H corresponding to the alignment mark 80 and a plurality of low-luminance regions 86L arranged with the high-luminance region 86H that is inserted therebetween from both sides in the x-axis direction. The plurality of low-luminance regions 86L correspond to regions of the target object Ma without the alignment mark 80.

Next, as shown in operation S22, the profile acquisition unit 91 may perform noise reduction. For example, the profile acquisition unit 91 may perform noise reduction by using a Gaussian filter.

Next, as shown in operation S23 and FIG. 26, the profile acquisition unit 91 performs averaging in the vertical direction. For example, the profile acquisition unit 91 forms one-dimensional data in the x-axis direction by averaging the luminance in the y-axis direction. Also, the profile acquisition unit 91 may form one-dimensional data in the y-axis direction by averaging the luminance in the x-axis direction. On the basis of the captured image of the region including the alignment mark 80 formed on the target object Ma as described above, a luminance profile in the x-axis direction of the ROI 82 including the high-luminance region 86H and the plurality of low-luminance regions 86L arranged on both sides of the alignment mark 80 in the x-axis direction is acquired. In other words, on the basis of the captured image of the region including the alignment mark 80 formed on the target object Ma, a luminance profile in one direction of the ROI including a first region, a second region, and a third region arranged in the one direction on the image is acquired. The second region corresponds to the alignment mark 80. The first region and the third region have a difference in luminance level from the second region.

Next, as shown in operation S24 and FIG. 18, the fitting unit 92 fits a fitting function, which includes a sigmoid function having an inflection point and a curvature, to the luminance profile. The fitting unit 92 estimates μ₁, μ₂, a₁, a₂, b, and c so that errors between the intensities at points on the luminance profile and the values of the fitting function are minimized. The calculated μ₁ and μ₂ represent the edge position 81L and the edge position 81R of the alignment mark 80, respectively. For example, the edge positions 81L and 81R of the alignment mark 80 are detected from the inflection points μ₁ and μ₂.

Next, as shown in operation S25 and FIG. 22, the position calculation unit 93 calculates the center position of the alignment mark 80 on the basis of the calculated edge position 81. When calculating the center position of the alignment mark 80, the position calculation unit 93 may calculate the center position in the x-axis direction and the center position in the y-axis direction. The center positions of the alignment marks 80 are detected as described above, and the misalignment between the alignment marks 80 is detected.

Next, an example of a method of determining the size of ROI 82 is described below, in which the size of ROI 82 is the same as the size of the luminance profile when fitting with the fitting function.

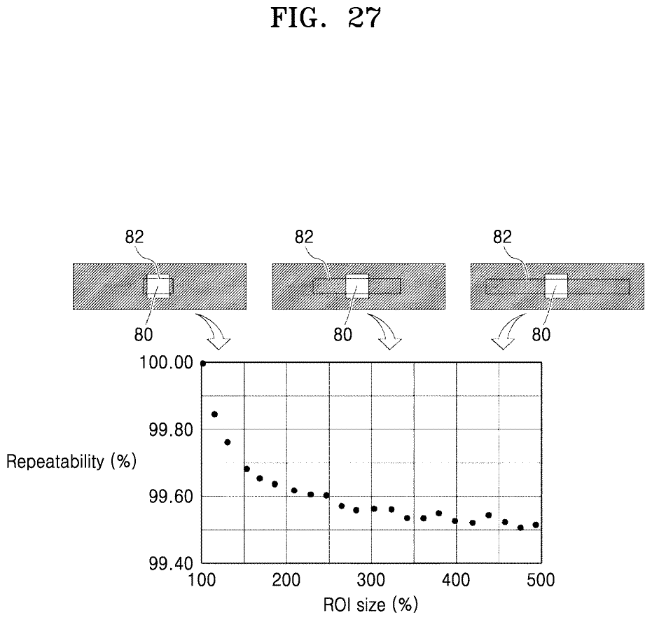

FIG. 27 is a graph illustrating examples of repeatability when the size of the ROI is changed in the mounting method according to some implementations. In FIG. 27, the horizontal axis represents the ratio of the length of the ROI 82 to the length of the alignment mark 80 in the x-axis direction and the vertical axis represents the repeatability. As the indicator of ‘Repeatability (%)’ on the vertical axis decreases, the repeatability is improved.

As shown in FIG. 27, as the size of the ROI 82 in the x-axis direction increases, the repeatability of the calculated edge position 81 of the alignment mark 80 is improved. For example, as the length of the ROI 82 increases to 200% or 300% of the length of the alignment mark 80, the repeatability of the edge position 81 is improved. This is based on the idea of the law of large numbers. That is, the luminance values of pixels are not uniform. Even with such non-uniformity, function fitting is performed using the luminance of many pixels, and thus, μ₁ and μ₂ representing the edge positions 81 may be converged to a certain average value. Accordingly, from the viewpoint of precision, it is desirable for the ROI 82 to be large in size.

Also, when the size of ROI 82 increases, two drawbacks occur. For example, a first drawback is that the inclusion of another mark 87 increases the error in function fitting and a second drawback is that the calculation time for detecting the edge position 81 increases. Accordingly, in order to perform positioning with high precision, it is necessary to determine the maximum range of the size of the ROI 82 by at least considering the first drawback described above.

The increase in error in function fitting due to including another mark 87 according to some implementations is described below.

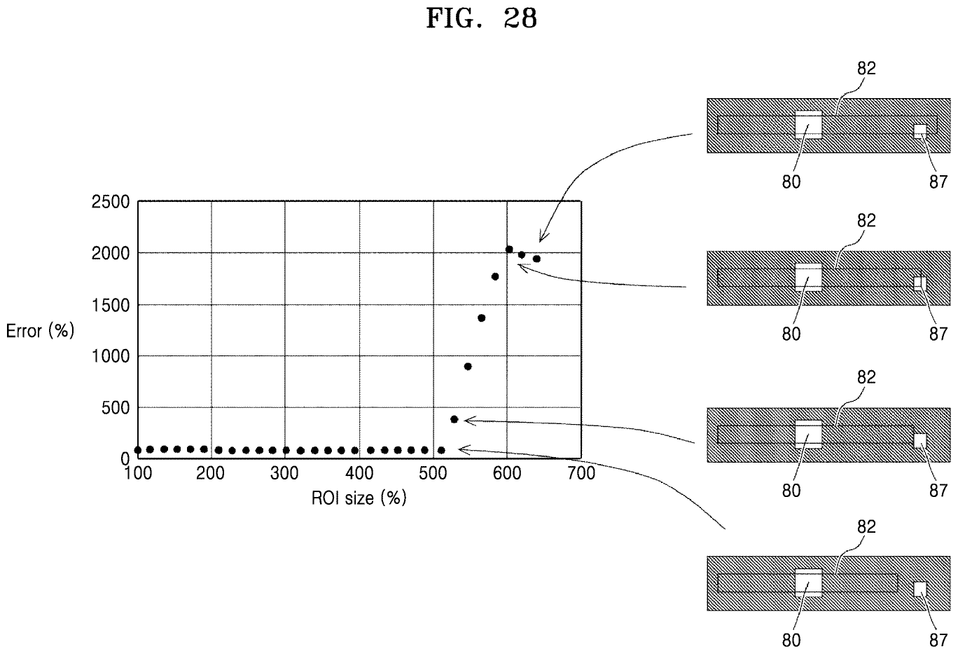

FIG. 28 is a graph illustrating an example of a case in which precision is deteriorated due to an increase in the size of the ROI in the mounting method according to some implementations. In FIG. 28, precision is deteriorated due to an increase in the size of the ROI 82 in the mounting method. Here, the horizontal axis represents the ratio of the length of the ROI 82 to the length of the alignment mark 80 in the x-axis direction and the vertical axis represents an error.

As shown in FIG. 28, the case, in which another mark 87 exists near the alignment mark 80 that is the detection target of the edge position 81, is examined. Even when the size of the ROI 82 increases to approach another mark 87, the luminance profile maintains the shape based on Equation (5) until the ROI 82 includes another mark 87. Accordingly, the fitting error is constant.

However, when the ROI 82 includes another mark 87, a new high-luminance region increases in the luminance profile. If so, the shape of the predicted luminance profile is different from the shape of the fitting function. Accordingly, the fitting error between the luminance profile and the fitting function increases. Accordingly, while changing the size of ROI 82, edge position detection processing, including noise reduction, vertical averaging, and fitting, is performed on luminance profiles of various sizes. The maximum range in which the fitting error is less than or equal to a threshold is set as the size of ROI 82. The threshold is set to a fitting error that may achieve the desired precision while changing the size of the ROI 82. Alternatively, a user may set the threshold.

As described above, the target object Ma may have, around the alignment mark 80, another mark 87 having higher luminance than the low-luminance region 86L. Also, when the ROI 82 includes another mark 87, the error between the luminance profile and the fitting function becomes larger than a certain value. Accordingly, the profile acquisition unit 91 obtains the luminance profile of the ROI 82 in the maximum range that satisfies that the error between the luminance profile and the fitting function is less than or equal to the certain value. In addition, with respect to another mark 87 described above, a second region includes a high-luminance region 86H, and each of first and third regions includes a low-luminance region 86L. When the second region includes the low-luminance region 86L and each of the first and third regions includes the high-luminance region 86H, another mark 87 described above has lower luminance than the first and third regions. Accordingly, the image may have a fourth region having higher luminance or lower luminance than the first region and the third region around the second region corresponding to the alignment mark 80, and the fourth region may correspond to another mark.

The increase in calculation time for detecting the edge position 81 according to some implementations is described below.

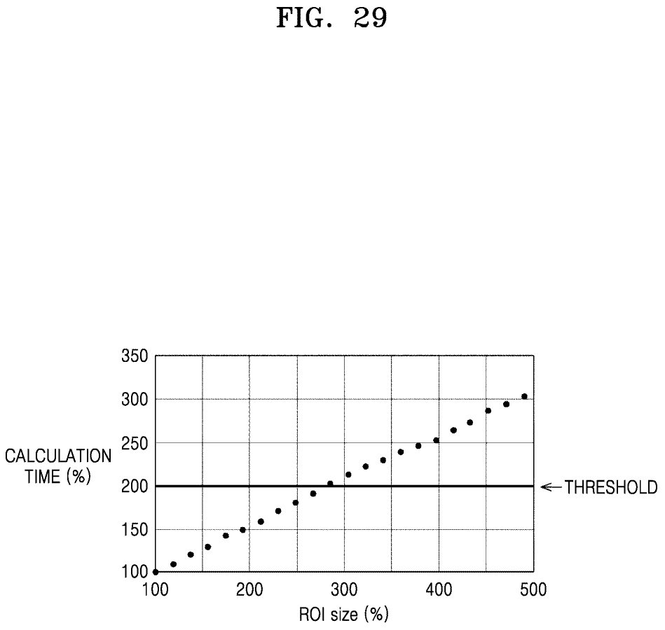

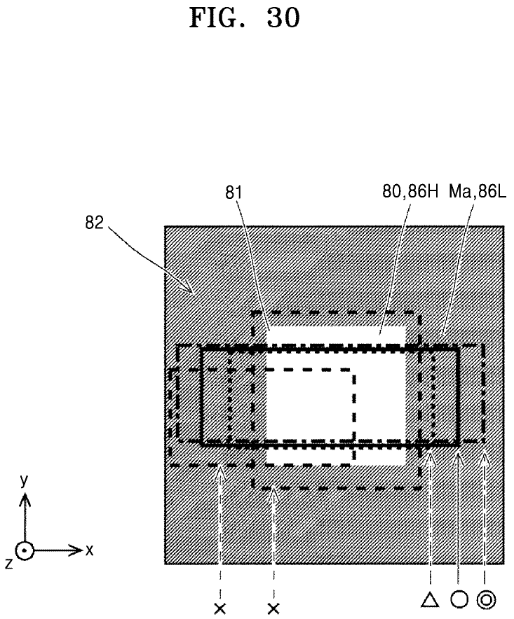

FIG. 29 is a graph illustrating an example of a relationship between the size of the ROI and a calculation time in the mounting method according some implementations. In FIG. 29, the relationship between the size of the ROI 82 and a calculation time in the mounting method are shown. Here, the horizontal axis represents the ratio of the length of the ROI 82 to the length of the alignment mark 80 in the x-axis direction and the vertical axis represents the calculation time.

As shown in FIG. 29, as the size of ROI 82 increases, the calculation time increases. This is because the number of accesses to data increases. Accordingly, the maximum size, which is the calculation time less than or equal to a threshold, is set to the size of ROI 82. The threshold may be determined in advance as a specification of the mounting device 1 or may be set by a user. As described above, the profile acquisition unit 91 obtains the luminance profile of the ROI 82 in the maximum range that satisfies that the calculation time for detecting the edge position 81 of the alignment mark 80 is less than or equal to a certain time.

As described above, the size of ROI 82 is determined by at least one of the range in which the luminance profile that does not deviate from the shape of the expected fitting function is obtained and the range in which the calculation time is allowable. Accordingly, edge detection having high repeatability may be performed.

As another method of determining the size of the ROI 82, the processing device 90 of the mounting device 1 may further include a graphical user interface (GUI). A user may determine the size of the ROI 82 using the GUI.

FIG. 30 is a diagram illustrating an example of a graphical user interface in the mounting device according to some implementations. In FIG. 30, the graphical user interface (GUI) may be used in the mounting device 1. As shown in FIG. 30, when the user sets the ROI 82, the ROI 82 may be displayed on the GUI. The user may change the size of the ROI 82 on the GUI by operating a mouse or the like. The GUI may display the ROI 82, which is determined by the above-described method of determining the size of the ROI 82, in other signs, such as a dotted line or a solid line, and may also show the policy by which the user determines the size of the ROI 82. Additionally, the quality level of each ROI 82 may be displayed on the GUI with symbols, such as excellent (⊚), good (∘), standard (Δ), and bad (x).

When determining the size of the ROI 82, the size once determined may be continuously used as long as the pattern of the alignment mark 80 of the target object Ma remains the same. For this reason, the size of the ROI 82 may be determined in advance during a process other than the processing flow of bonding the target object Ma. However, the timing of determining the size of ROI 82 is not limited thereto. For example, when the pattern of the alignment mark 80 of the target object Ma changes at high frequency, the size of the ROI 82 may be determined before cutting the ROI 82.

In some implementations, the mounting device 1 may be configured to fit the fitting function including the sigmoid curve to the luminance profile of the plurality of pixels on the image including the alignment mark 80. Accordingly, the mounting device 1 may reduce non-uniformity when detecting the center positions of the alignment mark 80 and improve the repeatability of detection of the alignment marks 80.

Since the number of pixels constituting the luminance profile is increased, the law of large numbers may be applied. Accordingly, the repeatability for detection of the center positions in the alignment marks 80 may be improved.

In addition, the luminance profile includes the edge position 81L and the edge position 81R at both ends of the alignment mark 80. Accordingly, compared to the case in which only one edge position 81 is provided, fitting using many pixels is possible. Specifically, the high-luminance region 86H and the low-luminance region 86L may be used for fitting as much as possible. Accordingly, the repeatability may be improved even when the amount of blurring of the alignment mark 80 is large or the alignment mark 80 is small. As a result, the precision of alignment may be improved, making high-precision bonding possible.

Furthermore, the profile acquisition unit 91 obtains the luminance profile of the ROI in the maximum range that satisfies that the error between the luminance profile and the fitting function is less than or equal to the certain value. Accordingly, the fitting error may be reduced. Also, the profile acquisition unit 91 may obtain the luminance profile of the ROI in the maximum range that satisfies that the calculation time for detecting the edge position 81 is less than or equal to a certain time. Accordingly, the calculation time may be shortened.

The mounting device 1 further includes the upper and lower dual FOV optical system that is inserted between the target object Ma and the target object Mb and simultaneously captures the images of the target object Ma and the target object Mb. Accordingly, the alignment may be performed based on the simultaneously captured images of the alignment mark 80 formed on the target object Ma and the alignment mark 80a formed on the target object Mb, and thus, high-precision mounting becomes possible.

A mounting program of executing on a computer comprises:
capturing an image of a region including an alignment mark formed on an object to be bonded and acquiring a luminance profile, in one direction, of a region of interest (ROI) including a first region, a second region and a third region arranged on the image in the one direction;
fitting a fitting function, which includes a sigmoid function having an inflection point and a curvature, into the luminance profile of the ROI to thereby detect an edge position of the alignment mark from the inflection point; and

Bonding another object to be bonded to the object to be bonded using the detected edge position of the alignment mark,
wherein the second region corresponds to the alignment mark, and
the first region and the third region have a difference in luminance level from the second region,
wherein the fitting function is expressed by

$$f ( x ) = ( \frac{1}{1 + exp ( - \frac{x - {μ}_{1}}{{a}_{1}} )} + \frac{1}{1 + exp ( - \frac{x - {μ}_{2}}{{a}_{2}} )} ) b + c ,$$

where μ₁ and μ₂ represent the inflection points,
a₁ and a₂ represent the curvatures, and

b and c represent constants.

The mounting program further comprises executing, on the computer,
calculating a center position of the alignment mark based on the detected edge position.

In the mounting program,
the second region has a quadrangular shape with sides in the one direction and sides in another direction intersecting with the one direction, and
the calculating of the center position of the alignment mark includes
calculating a first center position of the alignment mark in the one direction based on the edge position detected in the one direction and calculating a second center position of the alignment mark in another direction based on the edge position detected in another direction.

In the mounting program,
the obtaining of the luminance profile includes
obtaining the luminance profile of the ROI in a maximum range that satisfies at least one of a condition that an error between the luminance profile and the fitting function is less than or equal to a certain value and a condition that a calculation time for detecting the edge position is less than or equal to a certain time.

In the mounting program,
the image has a fourth region having higher luminance or lower luminance than the first region and the third region around the second region, and the fourth region corresponds to another mark,
wherein, when the ROI includes the fourth region, the error between the luminance profile and the fitting function becomes greater than the certain value.

In, the mounting program,
the ROI includes a first edge portion having an edge of the alignment mark between the first region and the second region on one side of the first region and a second edge portion having the edge between the first region and the second region on another side of the first region, and
the fitting function includes a first sigmoid function having the inflection point and the curvature of the first edge portion and a second sigmoid function having the inflection point and the curvature of the second edge portion.

The mounting program further comprises executing on the computer:
holding and supporting the object to be bonded by a bonding head;
holding and supporting another object to be bonded by a bonding stage, wherein another object to be bonded is bonded to the object to be bonded;
inserting an upper and lower dual FOV optical system between the one object to be bonded and another object to be bonded; and
capturing images of a first alignment mark and a second alignment mark by using a single image sensor in the upper and lower dual FOV optical system, wherein the first alignment mark corresponds to an alignment mark of the one object to be bonded and the second alignment mark corresponds to an alignment mark of another object to be bonded.

The program includes a group of instructions (or software code) for executing, on a computer, one or more functions described in the embodiment when the computer is loaded into the processing device 90. The program may be stored in a non-transitory computer-readable medium or a tangible storage medium. The computer-readable medium or the tangible storage medium may include, but not limited to: random-access memory (RAM), read-only memory (ROM), flash memory, a solid-state drive (SSD), or other memory devices; CD-ROM, a digital versatile disk (DVD), a Blu-ray (registered trademark) disk, or other optical disk storages; and a magnetic cassette, a magnetic tape, a magnetic disk storage, or other magnetic storage devices. The program may be transmitted on a temporary computer-readable medium or a communication medium. For example, the temporary computer-readable medium or the communication medium includes, but not limited to, an electrical signal, an optical signal, an acoustic signal, or other types of signals.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various implementations have been shown and described, it will be understood that changes in form and details may be made therein without departing from the spirit and scope of the following claims.

What is claimed is:

1. A mounting method comprising:
detecting an alignment mark position of a first object: and
bonding the first object to a second object based on a position of the alignment mark:
wherein the alignment mark position detecting method comprising:
capturing an image of a region comprising an alignment mark;
obtaining a luminance profile of the image; and
detecting a position of the alignment mark by fitting a fitting function to the luminance profile of the image; and
performing a bonding operation based upon the position of the alignment mark,
wherein the fitting function comprises a sigmoid function having an inflection point and a curvature.

2. The mounting method of claim 1, wherein the inflection point of the fitting function corresponds to an edge position of the alignment mark.

3. The mounting method of claim 2, further comprising detecting a center position of the alignment mark based on the edge position of the alignment mark.

4. The mounting method of claim 3, further comprising wherein, with respect to a first direction and a second direction different from the first direction:
calculating the center position of the alignment mark in a first direction as a midpoint of a first plurality of edge positions of the alignment mark that are spaced apart from each other in the first direction, and
calculating the center position of the alignment mark in a second direction different from the first direction as a midpoint of a second plurality of edge positions of the alignment mark that are spaced apart from each other in the second direction.

5. The mounting method of claim 1, wherein the fitting function comprises a plurality of inflection points and a plurality of curvatures.

6. The mounting method of claim 1,
wherein the obtaining of the luminance profile comprises obtaining a luminance profile of a region comprising a region of interest (ROI),
wherein at least a portion of the ROI comprises the alignment mark.

7. The mounting method of claim 6, wherein the ROI comprises a plurality of regions having different luminance levels.

8. The mounting method of claim 1, wherein luminance of the alignment mark is different from luminance of a region adjacent to the alignment mark.

9. A mounting method comprising:
capturing an image of a region comprising an alignment mark on a first object;
acquiring a luminance profile, in a first direction, of a region of interest (ROI) comprising a first region, a second region, and a third region arranged on the image in the first direction;
fitting a fitting function to the luminance profile of the ROI to detect an edge position of the alignment mark from the inflection point, wherein the fitting function comprises a sigmoid function having an inflection point; and
bonding a second object to the first object based on the detected edge position of the alignment mark,
wherein the second region comprises the alignment mark, and
wherein the first region and the third region have a difference in luminance level from the second region,
wherein the fitting function comprises
$$f ( x ) = ( \frac{1}{1 + exp ( - \frac{x - {μ}_{1}}{{a}_{1}} )} + \frac{1}{1 + exp ( - \frac{x - {μ}_{2}}{{a}_{2}} )} ) b + c ,$$
where μ₁ and μ₂ represent the inflection points, a₁ and a₂ represent the curvatures, and b and c represent constants.

10. The mounting method of claim 9, further comprising detecting a center position of the alignment mark based on the edge position of the alignment mark.

11. The mounting method of claim 10, wherein the second region has a quadrangular shape with sides in the first direction and sides in a second direction that intersect the first direction, and wherein the detecting of the center position of the alignment mark comprises calculating a first center position of the alignment mark in the first direction based on the edge position detected in the first direction and calculating a second center position of the alignment mark in the second direction based on the edge position detected in the second direction.

12. The mounting method of claim 9, wherein the acquiring of the luminance profile comprises acquiring the luminance profile of the ROI in a maximum range that satisfies at least one of a condition that an error between the luminance profile and the fitting function is less than or equal to a certain value and a condition that a calculation time for detecting the edge position is less than or equal to a certain time.

13. The mounting method of claim 12,
wherein the image includes a fourth region having higher luminance or lower luminance than the first region and the third region positioned around the second region, and the fourth region corresponds to another mark,
wherein, when the ROI comprises the fourth region, the error between the luminance profile and the fitting function becomes greater than the certain value.

14. The mounting method of claim 9,
wherein the ROI comprises a first edge portion having an edge of the alignment mark between the first region and the second region on one side of the first region and a second edge portion having the edge between the first region and the second region on another side of the first region, and
wherein the fitting function comprises a first sigmoid function having the inflection point and the curvature of the first edge portion and a second sigmoid function having the inflection point and the curvature of the second edge portion.

15. A mounting method comprising:
holding and supporting a first object to be bonded by a bonding head;
holding and supporting a second object to be bonded by a bonding stage;
inserting an upper and lower dual field-of-view (FOV) optical system between the first and second objects to be bonded;
capturing images of a first alignment mark on the first object and a second alignment mark on the second object using a single image sensor in the upper and lower dual FOV optical system;
detecting a position of each of the first alignment mark and the second alignment mark; and
bonding the first object and the second object to each other using the position of each of the first alignment mark and the second alignment mark,
wherein detecting the position of each of the first alignment mark and the second alignment mark comprises:
capturing an image of regions that comprise the first alignment mark and the second alignment mark;
obtaining a luminance profile of the image; and
detecting positions of the first alignment mark and the second alignment mark by fitting a fitting function to the luminance profile,
wherein the fitting function comprises a sigmoid function having an inflection point.

16. The mounting method of claim 15, wherein detecting the position of each of the first and second alignment marks comprises:
calculating an edge position of each of the first alignment mark and the second alignment mark based on the inflection point of the fitting function; and
calculating a center position of each of the first alignment mark and the second alignment mark based on an edge position of each of the first alignment mark and the second alignment mark.

17. The mounting method of claim 15, wherein the fitting function comprises a sum of a plurality of sigmoid functions.

18. The mounting method of claim 15, further comprising:
detecting misalignment between the first alignment mark and the second alignment mark; and
adjusting the misalignment between the first alignment mark and the second alignment mark.

19. The mounting method of claim 18,
wherein the detecting of the misalignment comprises calculating a distance between a center position of the first alignment mark and a center position of the second alignment mark, and
wherein the distance between the first alignment mark and the second alignment mark is calculated based on a horizontal distance between the first alignment mark and the second alignment mark.

20. The mounting method of claim 15, wherein the luminance profile comprises a plurality of regions having different luminance levels.
